(19) United States
(12) Patent Application Publication
(10) Pub. No.: US 2025/0166888 A1
(43) Pub. Date: May 22, 2025

(54) CURRENT TRANSFORMER

(71) Applicant: Delta Electronics, Inc., Taoyuan City (TW)

(72) Inventors: Yung-Sheng YEH, Taoyuan City (TW); Chih-Wei LIANG, Taoyuan City (TW)

(21) Appl. No.: 18/609,593

(22) Filed: Mar. 19, 2024

(30) Foreign Application Priority Data
Nov. 22, 2023 (CN) 202311566324.7

(51) Int. Cl. H01F 38/30; H01F 27/24; H01F 27/30

(52) U.S. Cl. CPC H01F 38/30; H01F 27/24; H01F 27/306

(57) ABSTRACT

A current transformer is provided, including a ferrite core and a coil. The ferrite core is formed in an open shape, having a first contact surface and a second contact surface. The coil is wound around the ferrite core, wherein when an induced current signal is generated in the coil, an imaginary line of the magnetic field extends through either the first contact surface or the second contact surface.

### CROSS REFERENCE TO RELATED APPLICATIONS

This application claims priority of China Patent Application No. 202311566324.7, filed on Nov. 22, 2023, the entirety of which is incorporated by reference herein.

### BACKGROUND OF THE INVENTION

### Field of the Invention

The present invention relates to a current transformer, and, in particular, to a current transformer that can be incorporated into a voltage transformer.

### Description of the Related Art

In the technological field of alternating current (AC), a current transformer (CT) is usually used to measure the frequency and magnitude of an AC current. Such a current transformer may, for example, be disposed in a voltage transformer to monitor the electrical current of the voltage transformer.

Conventional current transformers include a ferrite core in a closed shape and a coil wound around the ferrite core, wherein a conductive wire of the voltage transformer extends through the ferrite core. When an electrical current passes through the conductive wire, a magnetic flux is generated along the ferrite core, whereby an induced current signal can be generated in the coil. By detecting the induced current signal of the coil that is wound around the ferrite core, the electrical current of the voltage transformer can be monitored.

The ferrite core is usually designed to have an annular shape, to form the magnetic flux. However, it can be difficult to assemble the annular ferrite core of the current transformer directly to the voltage transformer. To solve this problem, the current transformer may be mounted to the voltage transformer via a positioning base.

The need for high power density has risen in recent years, and it has become more and more difficult to place the current transformer inside the voltage transformer due to the large dimensions of the positioning base and of the current transformer. Hence, the challenge is to reduce the size of the current transformer inside the voltage transformer and increase the power density of the voltage transformer.

### BRIEF SUMMARY OF THE INVENTION

An embodiment of the present invention provides a current transformer that includes a ferrite core and a coil. The ferrite core is formed in an open (non-closed) shape, having a first contact surface and a second contact surface. The coil is wound around the ferrite core, wherein when an induced current signal is generated in the coil, an imaginary line of the magnetic field extends through either the first contact surface or the second contact surface.

In some embodiments, the ferrite core is formed in a U shape, and the ferrite core includes a first leg portion and a second leg portion, the first contact surface is formed at the end of the first leg portion, and the second contact surface is formed at the end of the second leg portion.

In some embodiments, the ferrite core further includes a middle portion connected between the first and second leg portions, and the coil is wound around the middle portion.

In some embodiments, the ferrite core is formed in an I shape, and the ferrite core has a top end, a bottom end, and a long axis extending through the top end and the bottom end, the first contact surface is located at the top end, and the second contact surface is located at the bottom end.

In some embodiments, the ferrite core further includes a middle portion located in the middle of the ferrite core, and the coil is wound around the middle portion.

In some embodiments, the ferrite core is formed in a curved shape, and the ferrite core has a first end and a second end opposite to the first end, the first contact surface is located at the first end, and the second contact surface is located at the second end.

In some embodiments, the ferrite core further includes a middle portion located in the middle of the ferrite core, and the coil is wound around the middle portion.

In some embodiments, the ferrite core has a semicircular structure.

In some embodiments, the ferrite core forms a passage adjacent to the coil.

In some embodiments, the current transformer further includes a current output portion to transfer the induced current signal from the coil to an external device.

In some embodiments, the first contact surface and the second contact surface are parallel to a horizontal plane.

### BRIEF DESCRIPTION OF THE DRAWINGS

The present invention can be more fully understood by reading the subsequent detailed description and examples with references made to the accompanying drawings, wherein:

FIG. 1 is a perspective diagram of a current transformer 1 in accordance with a first embodiment of the invention.

FIG. 2 is a perspective diagram showing a voltage transformer 100 provided with the current transformer 1 of FIG. 1.

FIG. 3 is a partial exploded diagram of the voltage transformer 100 provided with the current transformer 1.

FIG. 4 is a schematic diagram showing the current transformer 1 when in use.

FIG. 5 is a perspective diagram of a current transformer 1′ in accordance with a second embodiment of the invention.

FIG. 6 is a schematic diagram showing the current transformer 1′ when in use.

FIG. 7 is a perspective diagram of a current transformer 1″ in accordance with a third embodiment of the invention.

FIG. 8 is a schematic diagram showing the current transformer 1″ when in use.

FIG. 9 is a perspective diagram of a current transformer 1′″ in accordance with a fourth embodiment of the invention.

FIG. 10 is a schematic diagram showing the current transformer 1′″ when joined to the recess 140 that is formed on the middle portion 112 of the ferrite core 110 of the voltage transformer 100.

FIG. 11 is a schematic diagram showing the current transformer 1 when disposed on the upper surface of the upper portion 111 of the ferrite core 110 of the voltage transformer 100.

### DETAILED DESCRIPTION OF THE INVENTION

The making and using of the embodiments of the current transformer are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

In the following detailed description of the preferred embodiments, reference is made to the accompanying drawings, and in which specific embodiments of which the invention may be practiced are shown by way of illustration. In this regard, directional terminology, such as “top,” “bottom,” “left,” “right,” “front,” “back,” etc., is used with reference to the orientation of the figures being described. The components of the present invention can be positioned in a number of different orientations. As such, the directional terminology is used for the purposes of illustration and is in no way limiting.

### First Embodiment

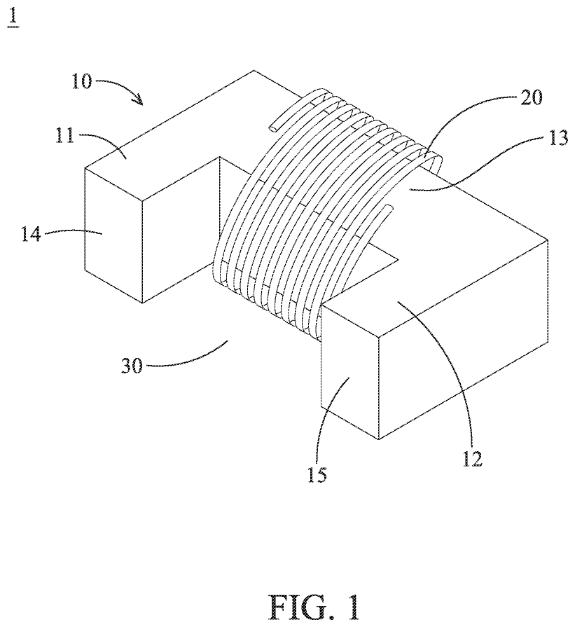

FIG. 1 is a perspective diagram of a current transformer 1 in accordance with a first embodiment of the invention.

In this embodiment, the current transformer 1 includes a ferrite core 10 and a coil 20. The ferrite core 10 is formed in an open (non-closed) shape and has a first contact surface 14 and a second contact surface 15. It should be noted that there is no space surrounded by the open (non-closed) shape such as U-shape, I-shape, arc-shape, or H-shape. In contrast, the closed shape can define and surround a space, such as annular, rectangular, or polygonal shape.

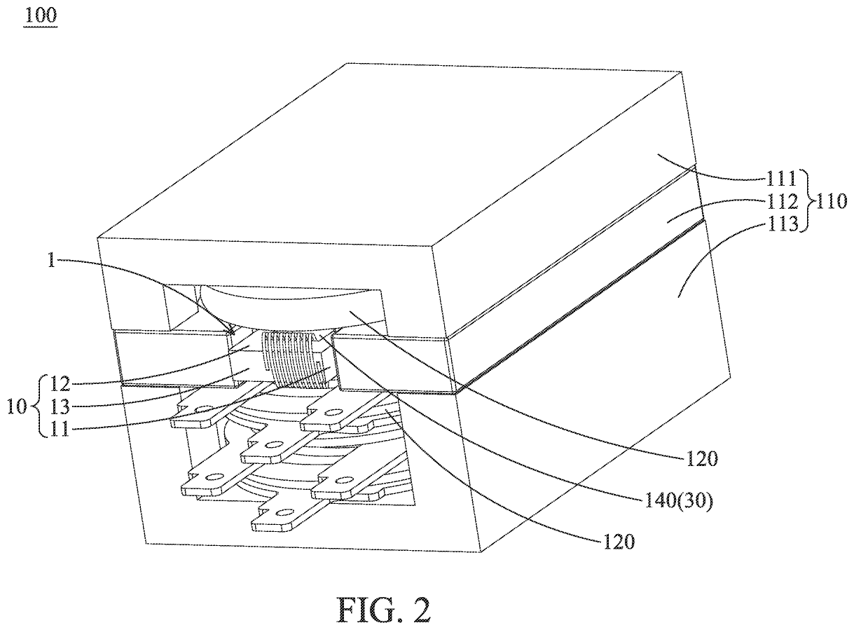

As shown in FIG. 1, the ferrite core 10 has a U-shaped structure including a first leg portion 11, a second leg portion 12, and a middle portion 13. The first contact surface 14 is formed at the end of the first leg portion 11, and the second contact surface 15 is formed at the end of the second leg portion 12. The first and second contact surfaces 14 and 15 are in contact with the ferrite core 110 of the voltage transformer 100 (FIG. 2) after assembly.

The middle portion 13 is connected between the first and second leg portions 11 and 12. Here, the first leg portion 11, the second leg portion 12, and the middle portion 13 forms a U-shaped structure that defines a passage 30. The coil 20 is wound on the outer surface of the middle portion 13 of the ferrite core 10 and located adjacent to the passage 30.

FIG. 2 is a perspective diagram showing a voltage transformer 100 provided with the current transformer 1 of FIG. 1.

Referring to FIG. 2, the voltage transformer 100 comprises a ferrite core 110 and a coil 120. The ferrite core 110 includes an upper portion 111, a middle portion 112, and a lower portion 113. In this embodiment, the upper portion 111, the middle portion 112, and the lower portion 113 are detachably connected to each other. In some embodiments, the ferrite core 110 may be integrally formed in one piece, and the invention is not limited to the embodiment depicted in FIG. 2.

The coil 120 is accommodated in the space between the upper and middle portions 111, 112 and the space between the middle and lower portions 112, 113. Specifically, the middle portion 112 forms a recess 140, and the current transformer 1 is received in the recess 140. After the current transformer 1 is disposed in the recess 140, the passage 30 denotes the remaining space of the recess 140 where the current transformer 1 does not occupy.

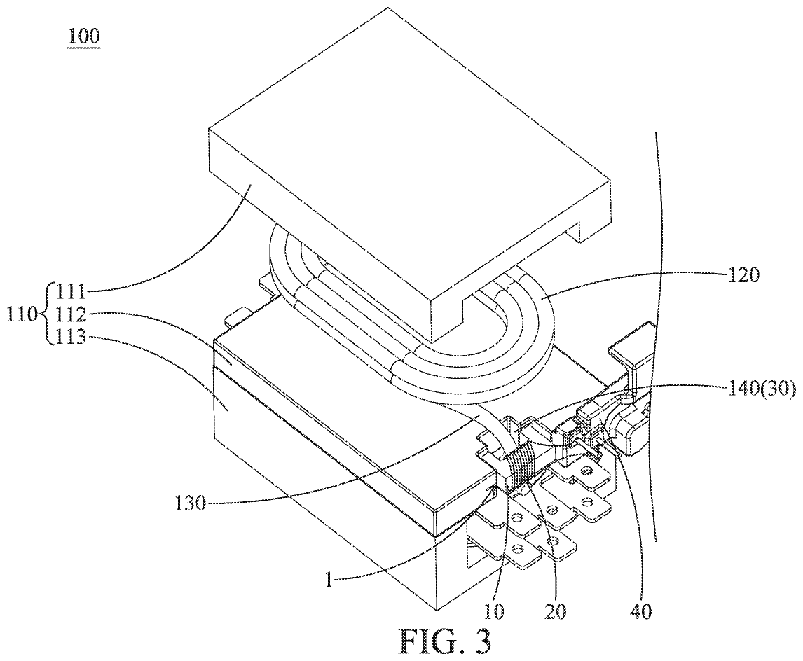

FIG. 3 is a partial exploded diagram of the voltage transformer 100 provided with the current transformer 1.

Referring to FIG. 3, the coil 120 has a conductive portion 130 that extends through the recess 140 (passage 30). The current transformer 1 has a current output portion 40 that is electrically connected to both ends of the coil 20, and an induced current signal in the coil 20 can be transferred to a supervision unit or other external devices through the current output portion 40.

In this embodiment, the recess 140 may be T-shaped, but the invention is not limited thereto. Any shape is acceptable if the current transformer 1 can be fitted in the recess 140 and the induced current signal can be generated in the coil 20. Additionally, the recess 140 may be formed on any surface of the ferrite core 110 rather than the surface of the middle portion 112. For example, the recess 140 may be formed on the surface of the upper portion 111 or the lower portion 113 for receiving the current transformer 1.

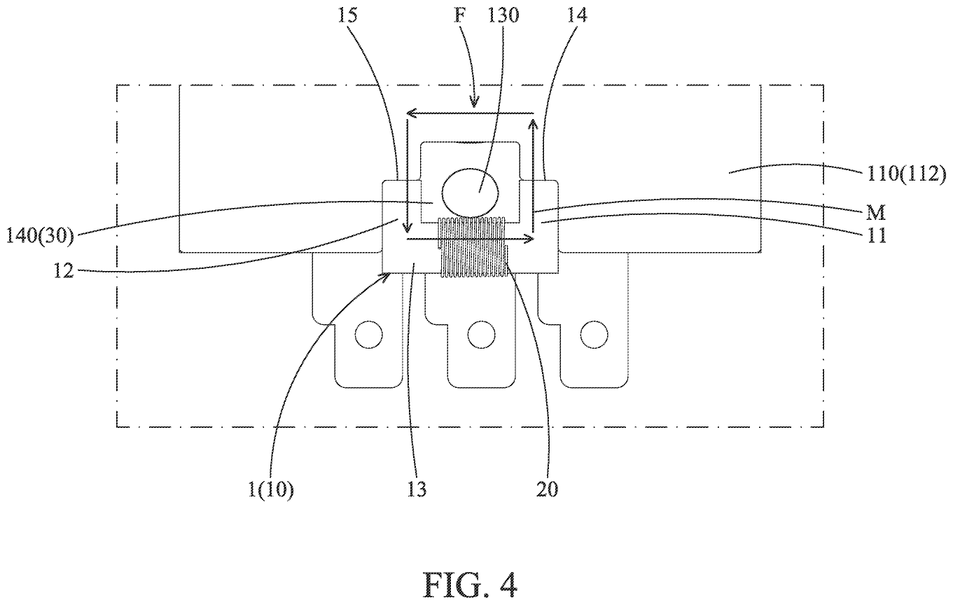

FIG. 4 is a schematic diagram showing the current transformer 1 when in use. Referring to FIG. 4, when the current transformer 1 is joined in the recess 140, the first contact surface 14 of the first leg portion 111 contacts the ferrite core 110 (middle portion 112), and the second contact surface 15 of the second leg portion 113 also contacts the ferrite core 110 (middle portion 112). When the conductive portion 130 extending through the recess 140 (passage 30) is energized by a current signal (either into the paper plane or out of the paper plane), a magnetic flux is generated around the conductive portion 130, as the line M of the magnetic field shows in FIG. 4.

The magnetic flux extends through the first contact surface 14 into the ferrite core 110 and through the second contact surface 15 back into the ferrite core 10. Hence, a closed magnetic path F is generated as shown in FIG. 4, and the induced current signal can be produced in the coil 20. With the induced current signal generated in the coil 20, we can imagine that a line M of the magnetic field extends through the first contact surface 14 along the closed magnetic path F into the ferrite core 110.

It should be noted that the induced current signal can be adjusted by changing the number of turns of the coil 20, whereby the output current signal of the coil 20 is equal to the current signal in the conductive portion 130. In some embodiments, the output current signal can be adjusted within an appropriate operation range suitable for the supervision unit.

Moreover, the conductive portion 130 may not generate the current signal on the primary side. Any current signal through the space defined between the ferrite core 110 and the ferrite core 10 (e.g. the recess 140 of the ferrite core 110 or the passage 30 of the ferrite core 10) is acceptable.

In this embodiment, the conventional annular current transformer can be replaced by the current transformer 1 with the U-shaped ferrite core 10, and the current transformer 1 can be accommodated in the ferrite core 110 of the voltage transformer 100 to save the space. Additionally, since the current transformer 1 with the U-shaped ferrite core 10 has a compact size to reduce the dimensions of the voltage transformer 100, the positioning base for the current transformer 1 is not needed, and high power density of the voltage transformer 100 can be achieved.

### Second Embodiment

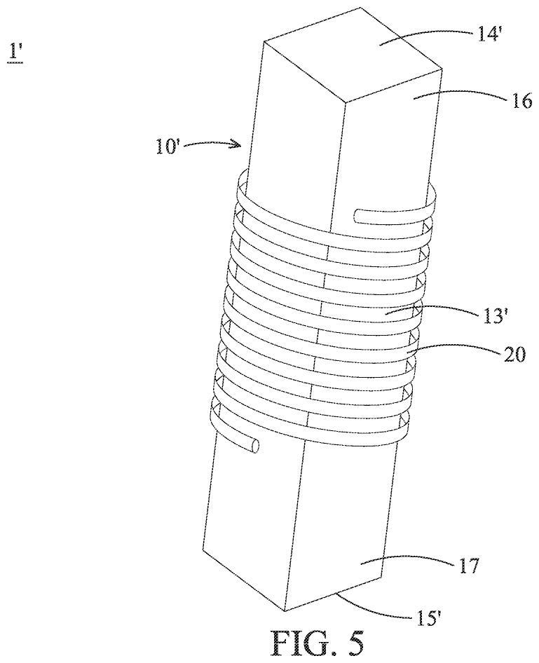

FIG. 5 is a perspective diagram of a current transformer 1′ in accordance with a second embodiment of the invention. It should be noted that the elements corresponding to those of FIGS. 1-6 share the same reference numerals, and explanation thereof is omitted for simplification of the description.

In this embodiment, the current transformer 1′ includes a ferrite core 10′ and a coil 20. The ferrite core 10′ is formed in an open (non-closed) shape and has a first contact surface 14′ and a second contact surface 15′.

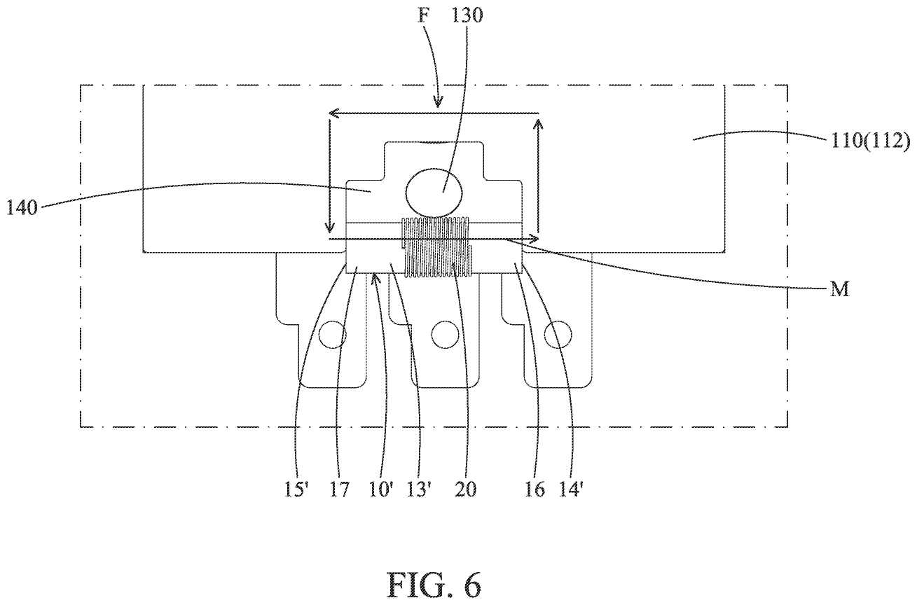

As shown in FIG. 5, the ferrite core 10′ has an I-shaped structure. The I-shaped structure defines a long axis, wherein the first contact surface 14′ is at the top end 16 of the ferrite core 10′, and the second contact surface 15′ is formed at the bottom end 17 of the ferrite core 10′. The first and second contact surfaces 14′ and 15′ are in contact with the ferrite core 110 of the voltage transformer 100 (FIG. 6) after assembly.

The ferrite core 10′ includes a middle portion 13′ located in the middle of the I-shaped ferrite core 10′, and the coil 20 is wound around the middle portion 13′ of the ferrite core 10′. On condition that the first and second contact surfaces 14′ and 15′ are able to contact the ferrite core 110 of the voltage transformer 100 (FIG. 6), the coil 20 may be wound on any portion of the ferrite core 10′ rather than the middle portion 13′.

FIG. 6 is a schematic diagram showing the current transformer 1′ when in use.

In this embodiment, the recess 140 is T-shaped, but the invention is not limited thereto. Any shape of the recess 140 is acceptable if the current transformer 1′ can be fitted in the recess 140 and the induced current signal can be generated in the coil 20. Additionally, the recess 140 may be formed on any portion of the ferrite core 110 rather than the middle portion 112. For example, the recess 140 may be formed on the surface of the upper portion 111 or the lower portion 113 to receive the current transformer 1′.

Referring to FIG. 6, when the current transformer 1′ is joined in the recess 140, the first contact surface 14′ at the top end 16 of the ferrite core 10′ contacts the ferrite core 110 (middle portion 112), and the second contact surface 15′ at the bottom end 17 of the ferrite core 10′ also contacts the ferrite core 110 (middle portion 112). When the conductive portion 130 extending through the recess 140 is energized by a current signal (either into the paper plane or out of the paper plane), a magnetic flux is generated around the conductive portion 130, as the line M of the magnetic field shows in FIG. 6.

Here, the magnetic flux extends through the first contact surface 14′ into the ferrite core 110 and through the second contact surface 15′ back into the ferrite core 10′. Hence, a closed magnetic path F is formed as shown in FIG. 6, and an induced current signal can be generated in the coil 20. With the induced current signal generated in the coil 20, we can imagine that a line M of the magnetic field extends through the first contact surface 14′ along the closed magnetic path F into the ferrite core 110.

It should be noted that the induced current signal can be adjusted by changing the number of turns of the coil 20, whereby the output current signal is equal to the current signal in the conductive portion 130. In some embodiments, the output current signal can be adjusted within an appropriate operation range suitable for the supervision unit.

Moreover, the conductive portion 130 may not generate the current signal on the primary side. Any current signal through the space defined between the ferrite core 110 and the ferrite core 10′ (e.g. the recess 140 of the ferrite core 110) is acceptable.

In this embodiment, the current transformer 1′ with I-shaped ferrite core 10′ can replace the conventional annular current transformer, and it can be accommodated in the ferrite core 110 of the voltage transformer 100 to save the space. Additionally, since the current transformer 1′ with the U-shaped ferrite core 10′ has a compact size to reduce the dimensions of the voltage transformer 100, the positioning base for the current transformer 1′ is not needed, and high power density of the voltage transformer 100 can be achieved.

When compared with the U-shaped ferrite core 10′ of the first embodiment (FIGS. 1-4), the I-shaped ferrite core 10′ of the current transformer 1′ (FIGS. 5 and 6) can have a more compact size to achieve high power density of the voltage transformer 100.

### Third Embodiment

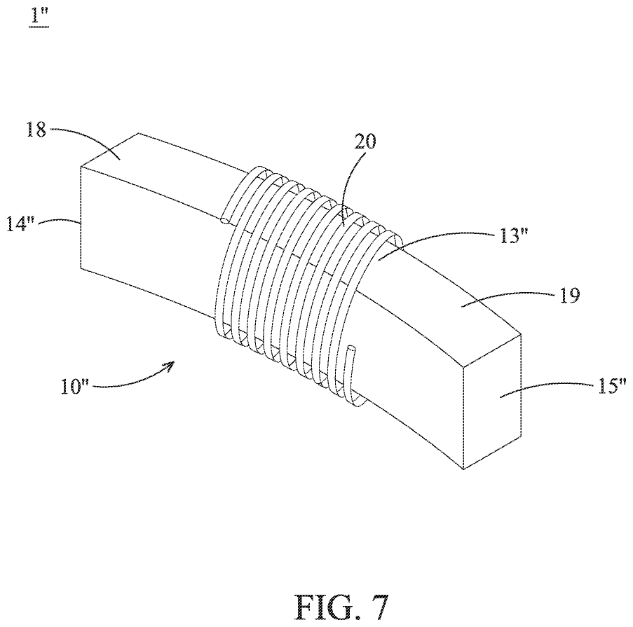

FIG. 7 is a perspective diagram of a current transformer 1″ in accordance with a third embodiment of the invention. It should be noted that the elements corresponding to those of FIGS. 1-8 share the same reference numerals, and explanation thereof is omitted for simplification of the description.

In this embodiment, the current transformer 1″ includes a ferrite core 10″ and a coil 20. The ferrite core 10″ is formed in an open (non-closed) shape and has a first contact surface 14″ and a second contact surface 15″.

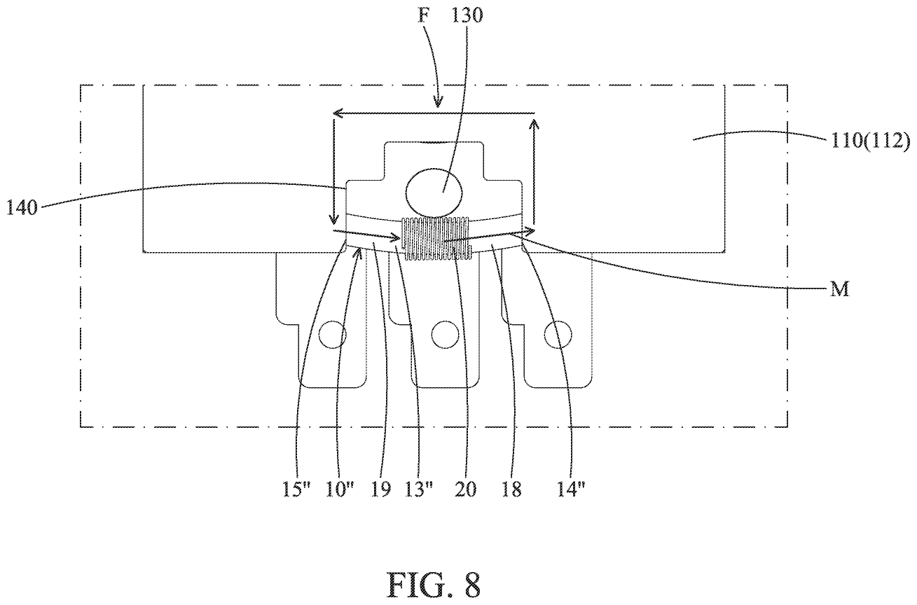

As shown in FIG. 7, the ferrite core 10″ has a curved structure. The curved structure has a first end 18 and a second end 19, wherein the first contact surface 14″ is formed at the first end 18 of the ferrite core 10″, and the second contact surface 15″ is formed at the second end 19 of the ferrite core 10″. The first and second contact surfaces 14″ and 15″ are in contact with the ferrite core 110 of the voltage transformer 100 (FIG. 8).

The ferrite core 10″ includes a middle portion 13″ located in the middle of the curved ferrite core 10″, and the coil 20 is wound around the middle portion 13″. On condition that the first and second contact surfaces 14″ and 15″ are able to contact the ferrite core 110 of the voltage transformer 100 (FIG. 8), the coil 20 may be wound on any portion of the ferrite core 10″ rather than the middle portion 13″. In some embodiments, the curved ferrite core 10″ may have an arc-shaped, C-shaped, or semicircular structure, and the invention is not limited to the embodiment depicted in FIG. 7.

In this embodiment, the recess 140 is T-shaped, but the invention is not limited thereto. Any shape is acceptable if the current transformer 1″ can be fitted in the recess 140 and the induced current signal can be generated in the coil 20.

FIG. 8 is a schematic diagram showing the current transformer 1″ when in use. Referring to FIG. 8, when the current transformer 1″ is accommodated in the recess 140, the first contact surface 14″ at the first end 18 of the ferrite core 10″ contacts the ferrite core 110 (middle portion 112), and the second contact surface 15 at the second end 19 of the ferrite core 10″ also contacts the ferrite core 110 (middle portion 112). When the conductive portion 130 extending through the recess 140 is energized by a current signal (either into the paper plane or out of the paper plane), a magnetic flux is generated around the conductive portion 130, as the line M of the magnetic field shows in FIG. 8.

The magnetic flux extends through the first contact surface 14″ into the ferrite core 110 and through the second contact surface 15″ back into the ferrite core 10″. Therefore, a closed magnetic path F is formed as shown in FIG. 8, and an induced current signal can be generated in the coil 20. With the induced current signal generated in the coil 20, we can imagine that a line M of the magnetic field extends through the first contact surface 14″ along the closed magnetic path F into the ferrite core 110.

It should be noted that the induced current signal can be adjusted by changing the number of turns of the coil 20, whereby the output current signal is equal to the current signal in the conductive portion 130. In some embodiments, the output current signal can be adjusted with in an appropriate operation range suitable for the supervision unit.

Moreover, the conductive portion 130 may not generate the current signal on the primary side. Any current signal through the space defined between the ferrite core 110 and the ferrite core 10″ (e.g. the recess 140 of the ferrite core 110) is acceptable.

In this embodiment, the current transformer 1″ with curved ferrite core 10″ can replace the conventional annular current transformer, and it can be joined in the ferrite core 110 of the voltage transformer 100 to save the space. Additionally, since the current transformer 1″ with curved ferrite core 10″ have compact size to reduce the dimensions of the voltage transformer 100, the positioning base for the current transformer 1″ is not needed, and high power density of the voltage transformer 100 can be achieved.

When compared with the U-shaped ferrite core 10 of the first embodiment (FIGS. 1-4), the curved ferrite core 10″ of the current transformer 1″ (FIGS. 7 and 8) can have a more compact size to achieve high power density of the voltage transformer 100.

### Fourth Embodiment

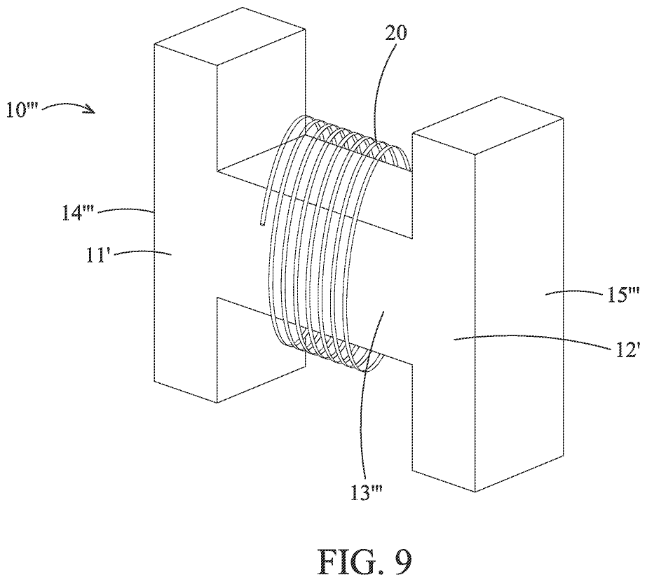

FIG. 9 is a perspective diagram of a current transformer 1′″ in accordance with a fourth embodiment of the invention. It should be noted that the elements corresponding to those of FIGS. 1-10 share the same reference numerals.

In this embodiment, the current transformer 1′″ includes a ferrite core 10′″ and a coil 20. The ferrite core 10′″ is formed in an open (non-closed) shape and has a first contact surface 14′″ and a second contact surface 15′″.

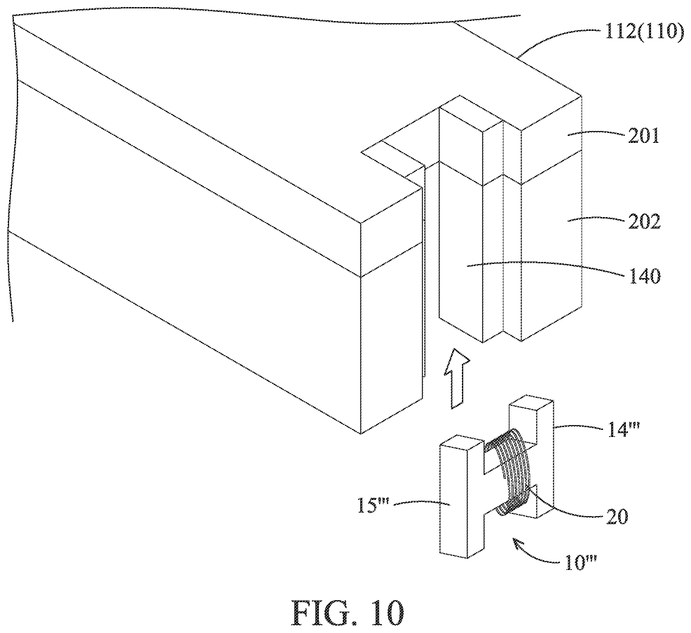

As shown in FIG. 9, the ferrite core 10′″ has an H-shaped structure. The H-shaped structure has a first leg portion 11″, a second leg portion 12′″, and a middle portion 13′″, wherein the first contact surface 14′″ is formed on the outer side of the first leg portion 11′″ of the ferrite core 10′″, and the second contact surface 15′″ is formed is formed on the outer side of the second leg portion 12′″ of the ferrite core 10′″, opposite to the first contact surface 14′″. The first and second contact surfaces 14′″ and 15′″ are in contact with the ferrite core 110 of the voltage transformer 100 (FIG. 10).

The middle portion 13″ of the ferrite core 10′″ is connected between the first and second leg portions 11′″ and 12′″. Specifically, the first leg portion 11′″, the second leg portion 12′″, and the middle portion 13′″ form an H-shaped structure, and the coil 20 is wound around the middle portion 13″.

FIG. 10 is a schematic diagram showing the current transformer 1″″ when joined to the recess 140 that is formed on the middle portion 112 of the ferrite core 110 of the voltage transformer 100.

Referring to FIG. 10, the middle portion 112 of the ferrite core 110 of the voltage transformer 100 comprises a first member 201 and a second member 202. The first member 201 may be an I-core, and the second member 202 may be an E-core. The first member 201 is stacked on the second member 202 to constitute the middle portion 112, and a recess 140 is formed on a side of the middle portion 112.

When the current transformer 1′″ is joined in the recess 140, the first contact surface 14′″ contacts the ferrite core 110 (middle portion 112), and the second contact surface 15′″ also contacts the ferrite core 110 (middle portion 112).

In this embodiment, the magnetic flux extends through the first contact surface 14″ into the ferrite core 110 and through the second contact surface 15″ back into the ferrite core 10′″, similar to the second embodiment as shown in FIG. 6, and explanation thereof is omitted for simplification of the description.

It should be noted that the conductive portion 130 may not generate the current signal on the primary side. Any current signal through the space defined between the ferrite core 110 and the ferrite core 10′″ (e.g. the recess 140 of the ferrite core 110) is acceptable.

The current transformer 1′″ with H-shaped ferrite core 10′″ can replace the conventional annular current transformer, and it can be accommodated in the ferrite core 110 of the voltage transformer 100 to save the space. Additionally, since the current transformer 1′″ with H-shaped ferrite core 10′″ have compact size to reduce the dimensions of the voltage transformer 100, the positioning base for the current transformer 1′″ is not needed, and high power density of the voltage transformer 100 can also be achieved.

When compared with the U-shaped ferrite core 10 of the first embodiment (FIGS. 1-4), the H-shaped ferrite core 10′″ of the current transformer 1′″ (FIGS. 9 and 10) have larger contact surfaces (the first and second contact surface 14′″ and 15′″) so that the H-shaped ferrite core 10′″ can be firmly affixed in the recess 140.

### Other Embodiments

In the first, second, and third embodiments, the first contact surface 14, 14′, 14″ and the second contact surface 15, 15′, 15″ are substantially parallel to the vertical direction, but the invention is not limited thereto. For example, the first contact surface 14, 14′, 14″ and the second contact surface 15, 15′, 15′ may be angled relative to the vertical direction. In some embodiments, the first contact surface 14, 14′, 14″ and the second contact surface 15, 15′, 15′ may have different tilt angles relative to the vertical direction.

Moreover, in the first, second, third, and fourth embodiments, only one current transformer is disposed in the voltage transformer, but the invention is not limited thereto. In some embodiments, two or more current transformer may be disposed on the same or different surfaces of the voltage transformer.

In the first, second, third, and fourth embodiments, the current transformer is disposed in the recess 140 of the voltage transformer 100, but the invention is not limited thereto. On condition that the ferrite cores of the current transformer and the voltage transformer can form a closed magnetic path F, the current transformer can be disposed on any surface of the voltage transformer.

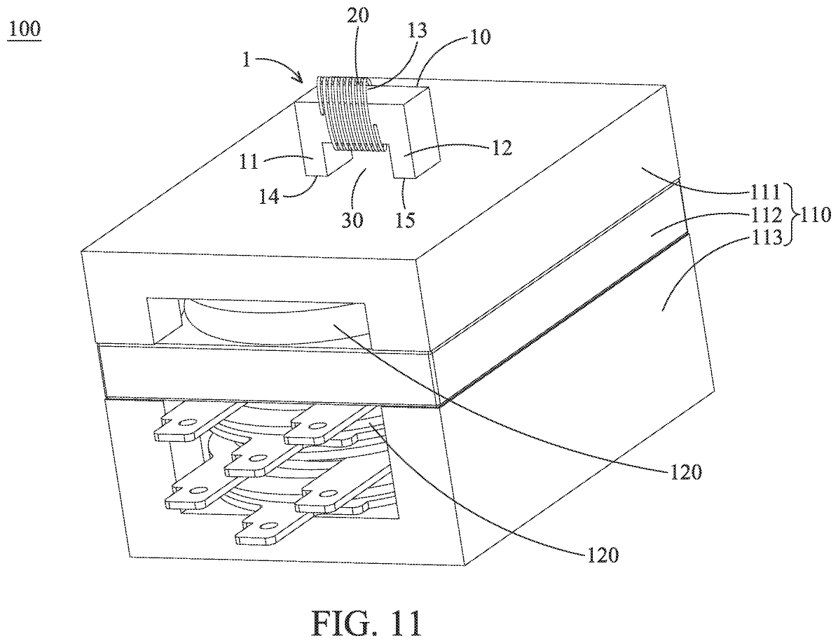

FIG. 11 is a schematic diagram showing the current transformer 1 when disposed on the upper surface of the upper portion 111 of the ferrite core 110 of the voltage transformer 100. It is noted that the conductive portion 130 of the coil 120 extending through the passage 30 of the ferrite core 10 is omitted from FIG. 11.

As shown in FIG. 11, the ferrite core 110 of the voltage transformer 100 does not form the recess 140 as disclosed in the first, second, third, and fourth embodiments. In this configuration, the current transformer 1 can be disposed on the upper surface of the ferrite core 110 (upper portion 111) of the voltage transformer 100. Hence, the first contact surface 14 and the second contact surface 15 are parallel to the horizontal plane and in contact with the upper surface of the ferrite core 110.

With the ferrite cores 10 and 110 of the current transformer 1 and the voltage transformer 100 forming a closed magnetic path, the magnetic flux can be generated along the closed magnetic path to produce an induced current signal through the coil 20. When compared with the conventional current transformers, the voltage transformer 100 can have compact size to achieve high power density.

It should be noted that though the current transformers 1, 1′, 1″, 1′″ in the first, second, third, and fourth embodiments are incorporated in the voltage transformer 100, the invention is not limited to the aforementioned embodiments. The current transformer can also be disposed in any device if an induced current signal can be generate in the coil of the current transformer.

In summary, the invention provides a current transformer that can be embedded in the voltage transformer 100, whereby the positioning base for the current transformer is not needed to save the space. Therefore, high power density of the voltage transformer 100 can be achieved. The current transformer can also be disposed in other devices to save the space and the cost of the positioning base.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, compositions of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure.

Accordingly, the appended claims are intended to include within their scope such processes, machines, manufacture, compositions of matter, means, methods, or steps. Moreover, the scope of the appended claims should be accorded the broadest interpretation so as to encompass all such modifications and similar arrangements.

While the invention has been described by way of example and in terms of preferred embodiment, it should be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A current transformer, comprising:
a ferrite core, formed in an open shape, having a first contact surface and a second contact surface; and
a coil, wound around the ferrite core, wherein when an induced current signal is generated in the coil, an imaginary line of a magnetic field extends through the first contact surface or the second contact surface.

2. The current transformer as claimed in claim 1, wherein the ferrite core is formed in a U shape, and the ferrite core includes a first leg portion and a second leg portion, the first contact surface is formed at the end of the first leg portion, and the second contact surface is formed at the end of the second leg portion.

3. The current transformer as claimed in claim 2, wherein the ferrite core further includes a middle portion connected between the first and second leg portions, and the coil is wound around the middle portion.

4. The current transformer as claimed in claim 1, wherein the ferrite core is formed in an I shape, and the ferrite core has a top end, a bottom end, and a long axis extending through the top end and the bottom end, the first contact surface is located at the top end, and the second contact surface is located at the bottom end.

5. The current transformer as claimed in claim 4, wherein the ferrite core further includes a middle portion located in the middle of the ferrite core, and the coil is wound around the middle portion.

6. The current transformer as claimed in claim 1, wherein the ferrite core is formed in a curved shape, and the ferrite core has a first end and a second end opposite to the first end, the first contact surface is located at the first end, and the second contact surface is located at the second end.

7. The current transformer as claimed in claim 6, wherein the ferrite core further includes a middle portion located in the middle of the ferrite core, and the coil is wound around the middle portion.

8. The current transformer as claimed in claim 6, wherein the ferrite core has a semicircular structure.

9. The current transformer as claimed in claim 1, wherein the ferrite core forms a passage adjacent to the coil.

10. The current transformer as claimed in claim 1, further comprising a current output portion to transfer the induced current signal from the coil to an external device.

11. The current transformer as claimed in claim 1, wherein the first contact surface and the second contact surface are parallel to a horizontal plane.
